(19) United States
(12) Patent Application Publication
(10) Pub. No.: US 2025/0037992 A1
(43) Pub. Date: Jan. 30, 2025

(54) DEPOSITION OF HIGH COMPRESSIVE STRESS THERMALLY STABLE NITRIDE FILM

(71) Applicant: Lam Research Corporation, Fremont, CA (US)

(72) Inventors: Soumana HAMMA, Tigard, OR (US); Fayaz A. SHAIKH, Lake Oswego, OR (US)

(21) Appl. No.: 18/713,068

(22) PCT Filed: Nov. 29, 2022
(86) PCT No.: PCT/US2022/080562

§ 371 Date: May 23, 2024

Related U.S. Application Data
(60) Provisional application No. 63/264,722, filed on Dec. 1, 2021.

(51) Int. Cl. H01L 21/02

(52) U.S. Cl. CPC H01L 21/02274; H01L 21/0217; H01L 21/02211

(57) ABSTRACT

A high-stress, thermally-stable compressive nitride film is deposited on a semiconductor substrate. The compressive nitride film may be deposited by plasma-enhanced chemical vapor deposition (PECVD) under conditions that produce a compressive nitride film with high compressive film stress and with a minimal stress shift when exposed to a temperature greater than a deposition temperature of the compressive nitride film. In some implementations, the compressive nitride film is a silicon nitride film. The PECVD conditions may reduce a number of Si—H bonds in the silicon nitride to obtain improved thermal stability. In some implementations, the high-stress, thermally-stable nitride film is deposited on a backside of the semiconductor substrate for wafer bow compensation.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD

Implementations herein relate to semiconductor fabrication and, more particularly, to wafer bow compensation using highly tensile or highly compressive stress films.

### BACKGROUND

Semiconductor manufacturing processes involve many deposition and etching operations, which can change wafer bow drastically. For example, in 3D-NAND fabrication, which is gradually replacing 2D-NAND chips due to lower cost and higher reliability in various applications, multi-stacked films with thick, high stress carbon-based hard masks and/or metallization lines can cause significant wafer warpage, leading to frontside lithographic overlay mismatch, or even wafer bow beyond a chucking limit of an electrostatic chuck.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the present disclosure.

### SUMMARY

Provided herein is a method of depositing a compressive nitride film on a bowed semiconductor substrate. The method includes providing a bowed semiconductor substrate having one or more regions of tensile stress and one or more regions of compressive stress, and depositing, by plasma-enhanced chemical vapor deposition (PECVD) at a deposition temperature, a compressive nitride film on a backside of the bowed semiconductor substrate. The compressive nitride film has a compressive film stress, where the compressive nitride film has a stress shift equal to or less than 40% of the compressive film stress when exposed to a temperature greater than the deposition temperature.

In some implementations, the compressive nitride film is undoped silicon nitride, oxygen-doped silicon nitride, or carbon-doped silicon nitride. In some implementations, the compressive nitride film is undoped silicon nitride. In some implementations, the compressive film stress of the compressive nitride film is equal to or greater than about 400 MPa. In some implementations, the compressive film stress of the compressive nitride film is between about 1000 MPa and about 2000 MPa. In some implementations, the stress shift of the compressive nitride film is equal to or less than 35% of the compressive film stress when exposed to a temperature equal to or greater than about 850° C. In some implementations, the method further includes depositing a tensile nitride film on the backside of the bowed semiconductor substrate, where the tensile nitride film is deposited in the one or more regions of compressive stress and the compressive nitride film is deposited in the one or more regions of tensile stress to mitigate bowing on a frontside of the bowed semiconductor substrate. In some implementations, depositing the compressive nitride film by PECVD includes exposing the backside of the bowed semiconductor substrate to a silicon-containing precursor and a nitrogen-containing reactant, and exposing the backside of the bowed semiconductor substrate to plasma to drive a reaction between the silicon-containing precursor and the nitrogen-containing reactant to deposit the compressive nitride film. In some implementations, the plasma is generated using a low-frequency radio-frequency (LFRF) power that is less than a high-frequency radio-frequency (HFRF) power. In some implementations, the LFRF power is equal to or less than about 40% of a total RF power applied between the LFRF power and the HFRF power. In some implementations, the silicon-containing precursor includes silane, where a flow rate of silane is equal to or less than about 5% by volume of a total gas flow of a gas mixture in PECVD. In some implementations, a number of N—H bonds is greater than a number of Si—H bonds in the compressive nitride film, and a number of Si—N bonds is substantially greater than the number of Si—H bonds in the compressive nitride film.

Also provided herein is a method of depositing a silicon nitride film on a semiconductor substrate. The method includes exposing a semiconductor substrate in a reaction chamber to a silicon-containing precursor and a nitrogen-containing reactant, generating plasma in the reaction chamber using an LFRF power that is less than an HFRF power, and exposing the semiconductor substrate to the plasma in the reaction chamber to drive a PECVD reaction between the silicon-containing precursor and the nitrogen-containing reactant to deposit a silicon nitride film on the semiconductor substrate at a deposition temperature. The silicon nitride film has a compressive film stress, and the silicon nitride film has a stress shift equal to or less than 40% of the compressive film stress when exposed to a temperature greater than the deposition temperature.

In some implementations, the compressive film stress of the silicon nitride film is equal to or greater than about 400 MPa. In some implementations, the compressive film stress of the silicon nitride film is between about 1000 MPa and about 2000 MPa. In some implementations, the stress shift is equal to or less than 35% of the compressive film stress when exposed to a temperature equal to or greater than about 850° C. In some implementations, the silicon nitride film has a thickness equal to or less than about 300 nm. In some implementations, the LFRF power is equal to or less than about 40% of a total RF power applied between the LFRF power and the HFRF power. In some implementations, a number of N—H bonds is greater than a number of Si—H bonds in the silicon nitride film, and a number of Si—N bonds is substantially greater than the number of Si—H bonds in the silicon nitride film. In some implementations, the semiconductor substrate is a bowed semiconductor substrate having one or more tensile regions, wherein the silicon nitride film mitigates bowing in the one or more tensile regions of the bowed semiconductor substrate.

### BRIEF DESCRIPTION OF THE DRAWINGS

FIG. 1 shows a perspective view of a bowed semiconductor substrate illustrating wafer bowing in an x-axis direction and a y-axis direction.

FIG. 2 shows a top view schematic illustration of an example bowed semiconductor substrate divided into regions of tensile stress and regions of compressive stress according to some implementations.

FIG. 3 illustrates a flow diagram of an example method of depositing a compressive nitride film on a bowed semiconductor substrate according to some implementations.

FIGS. 4A-4C show cross-sectional schematic illustrations of various stages of forming a compressive nitride layer to mitigate bowing caused by regions of tensile stress in a bowed semiconductor substrate according to some implementations.

FIG. 5 illustrates a graph showing an IR spectrum for a conventional silicon nitride film deposited by plasma enhanced chemical vapor deposition (PECVD) and an IR spectrum for a high-stress, thermally-stable silicon nitride film deposited by PECVD according to some implementations.

FIG. 6 shows a graph illustrating stress shift for a conventional silicon nitride film deposited by PECVD and a stress shift for a high-stress, thermally-stable silicon nitride film deposited by PECVD according to some implementations.

FIG. 7 illustrates a flow diagram of an example method of depositing a silicon nitride film on a semiconductor substrate according to some implementations.

FIG. 8 shows a schematic diagram of an example plasma processing apparatus configured to perform PECVD according to some implementations.

FIG. 9 shows a schematic diagram of an example process tool for substrate processing according to some implementations.

### DETAILED DESCRIPTION

In the present disclosure, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication. A wafer or substrate used in the semiconductor device industry typically has a diameter of 200 mm, or 300 mm, or 450 mm. The following detailed description assumes the present disclosure is implemented on a wafer. However, the present disclosure is not so limited. The work piece may be of various shapes, sizes, and materials.

Semiconductor fabrication processes involve formation of various structures, many of which may be two-dimensional. As semiconductor device dimensions shrink and devices are scaled to be smaller, the density of features across a semiconductor substrate increases, resulting in layers of material etched and deposited in various ways, including in three dimensions. For example, 3D-NAND is one technology that is becoming increasingly popular due to lower cost and increased memory density compared to other techniques, such as 2D-NAND, and higher reliability in various applications. During the fabrication of a 3D-NAND structure, wafer bow can change drastically. For example, deposition of thick hard mask materials and etching of trenches along a wafer surface in fabricating a 3D-NAND structure can cause wafer bowing.

As layers of films are stacked on top of each other during fabrication, more stress is introduced to the semiconductor wafer which can cause bowing. The bowing can have various shapes. In a concave-shaped wafer, sometimes referred to as a “smiling wafer” or a bow-shaped wafer, the lowest point is the center of the wafer and the highest point is the edge of the wafer. In a convex-shaped wafer, sometimes referred to as a “sad wafer” or dome-shaped wafer, the lowest point is the edge of the wafer and the highest point is the center of the wafer.

Bowing can be measured using an optical technique. Wafer bowing can be measured or evaluated by obtaining a wafer map or stress map. Bowing can be quantified using a bow value or warpage value as described herein, which is measured as the vertical distance between the lowest point of the semiconductor wafer to the highest point on the wafer. The warpage value can be along one or more axes—for example, an asymmetrically warped wafer may have an x-axis warpage and/or a y-axis warpage.

In a bow-shaped wafer, the lowest point is the center of the wafer and the highest point is the edge of the wafer. In a dome-shaped wafer, the lowest point is the edge of the wafer and the highest point is the center of the wafer. Bow-shaped and dome-shaped wafers have symmetrical or largely symmetrical bowing. Wafers can also have asymmetric bowing. In asymmetric bowing, warpage is measured along an x-axis and a y-axis. An asymmetrically bowed wafer has different values for the x-axis warpage and y-axis warpage. In some cases, an asymmetrically bowed wafer has a negative x-axis warpage and a positive y-axis warpage. In some cases, an asymmetrically bowed wafer has a positive x-axis warpage and a negative y-axis warpage. In some cases, an asymmetrically bowed wafer has both a positive x-axis warpage and a positive y-axis warpage, but the warpage values are different. In some cases, an asymmetrically bowed wafer has both a negative x-axis warpage and a negative y-axis warpage, but the warpage values are different. One example of an asymmetrically bowed wafer is a saddle-shaped wafer. For a saddle-shaped wafer, in one example, the warpage on the x-axis may be +200 μm and the warpage on the y-axis may be −200 μm. Saddle-shaped wafers have two opposing edges of the wafer that are curved upward while another two opposing edges of the wafer are curved downward. As used herein, warpage can refer to any deviation from planarity exhibited by a wafer, where a bow-shaped wafer, dome-shaped wafer, and saddle-shaped wafer are examples of different types of warpage in a wafer.

Bowing can cause numerous problems with subsequent processing if the substrate is warped. For example, during lithography, etching can be uneven if the substrate is warped. This can lead to problems associated with defocus and overlay degradation, which can lead to major yield loss. High bowing can be caused by deposition of thick, high stress hard mask layer. Additionally, due to multi-stacked films and the presence of thick, high stress hard masks used in such fabrication processes, etching can cause some asymmetric warpage and deposition processes can introduce significant wafer warpage of up to a variation between +500 μm to −1300 μm bow. For example, an ashable hard mask may have a stress value of up to −1000 MPa and have a bow value of up to −1000 μm. In some cases, a high aspect ratio slit etch and metal fill (e.g., tungsten fill) can induce large anisotropic stress on the semiconductor substrate.

Addressing such wafer warpage can be a challenge as subsequent or downstream processing may be affected by a wafer warpage exceeding ±200 μm, exceeding ±300 μm or exceeding ±500 μm. For instance, mechanical wafer handling may be affected due to wafer warpage, where wafers that are not flat may not be gripped or held effectively by a wafer robot or wafer handling mechanism. Additionally, wafer warpage may contribute to process non-uniformity, where downstream etch, deposition, or clean operations may be adversely affected due to processing non-uniformities across a surface of the wafer. In some cases, processing of highly warped wafers may cause further warping. For example, etching of a trench in one direction can cause warping in asymmetric bowing due to asymmetric stress on the wafer. Moreover, lithography operations may be adversely affected by wafer warpage as precise patterns are unable to be formed. When wafers are used in subsequent processing that involve chucking of the wafer to an electrostatic chuck, highly warped wafers may not be processed in some tools. Many electrostatic chucks have a “chucking limit,” which is defined as the maximum warpage tolerated before the wafer cannot be effectively chucked. For example, some electrostatic chucks have a chucking limit of about ±300 μm. Warped wafers that exceed the chucking limit may not be processed in such instances.

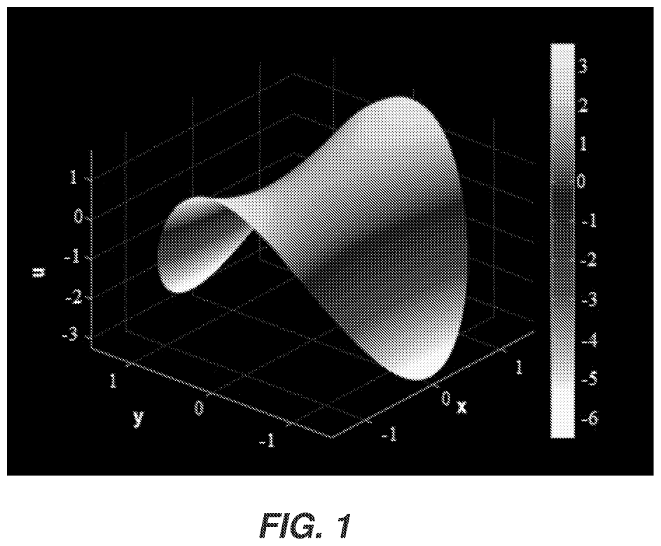

FIG. 1 shows a perspective view of a bowed semiconductor substrate illustrating wafer bowing in an x-axis direction and a y-axis direction. The bowed semiconductor substrate is superimposed in a three-dimensional (3-D) coordinate system, with a reference plane of the bowed semiconductor substrate defined by the x-axis direction and y-axis direction, and with the u-axis indicative of warpage. As shown in FIG. 1, the bowed semiconductor substrate is asymmetrically bowed, meaning that the values for x-axis warpage and y-axis warpage are different. This creates bowing that is saddle-shaped. As discussed above, warpage refers to any deviation from planarity exhibited by a semiconductor substrate, where a saddle-shaped wafer represents an example of warpage in a semiconductor substrate.

Some techniques exist for addressing symmetric bowing of semiconductor wafers, and in some cases, techniques can be used to reduce warpage by changing the process for fabricating the desired layers in the substrate. However, few techniques exist for compensating for asymmetric bowing such as saddle-shaped bowing. The complexity of current technologies leads to more complex wafer bowing shapes such as saddle-shaped bowing.

To reduce wafer bowing, one or more layers of material may be deposited onto a backside of the wafer. These layers deposited onto the backside of wafers may be considered bow compensation layers. In general, characteristics of the bow compensation layer, including its thickness and composition, for example, affects the amount of bow that can be compensated by that layer. For instance, the thicker the bow compensation layer becomes, the more bow compensation may result. Moreover, characteristics of the bow compensation layer may be affected by controlling deposition conditions of the bow compensation layer. This can affect how tensile or compressive a bow compensation layer is.

To compensate for complex wafer warpage shapes, the one or more layers of materials deposited onto the backside of the wafer may be a mix of compressive and tensile films. A compressive bow compensation layer may be deposited on the backside of the wafer on regions having compressive stress and a tensile bow compensation layer may be deposited on the backside of the wafer on regions having tensile stress. Silicon oxide films deposited by PECVD typically have compressive stress, and silicon nitride films deposited by PECVD typically have tensile stress. Thus, a combination of silicon oxide and silicon nitride films deposited by PECVD are ordinarily employed as bow compensation layers for compensating asymmetric wafer warpage.

“Silicon oxide” is referred to herein as including chemical compounds including silicon and oxygen atoms, including any and all stoichiometric possibilities for SiₓO_{y}, including integer values of x and y and non-integer values of x and y. For example, “silicon oxide” includes compounds having the formula SiOₙ, where 1≤n≤2, where n can be an integer or non-integer values. “Silicon oxide” can include sub-stoichiometric compounds such as SiO_{1.8}. “Silicon oxide” also includes silicon dioxide (SiO₂) and silicon monoxide (SiO). “Silicon oxide” also includes both natural and synthetic variations and also includes any and all crystalline and molecular structures, including tetrahedral coordination of oxygen atoms surrounding a central silicon atom. “Silicon oxide” also includes amorphous silicon oxide and silicates. Silicon oxide may also include trace amounts or interstitial amounts of hydrogen (SiOH). Silicon oxide may also include trace amounts of nitrogen, particularly if nitrogen gas is used as a carrier gas (SiON).

“Silicon nitride” is referred to herein as including any and all stoichiometric possibilities for SiₓN_{y}, including integer values of x and y and non-integer values of x and y; for example, a ratio X: Y may be 3:4. For example, “silicon nitride” includes compounds having the formula SiNₙ, where 1≤n≤2, where n can be an integer or non-integer values. “Silicon nitride” can include sub-stoichiometric compounds such as SiN_{1.8}. “Silicon nitride” also includes Si₃N₄ and silicon nitride with trace and/or interstitial hydrogen (SiNH) and silicon nitride with trace amounts of or interstitial oxygen (SiON) or both (SiONH). “Silicon nitride” also includes both natural and synthetic variations and also includes any and all lattice, crystalline, and molecular structures, including trigonal alpha-silicon nitride, hexagonal beta-silicon nitride, and cubic gamma-silicon nitride. “Silicon nitride” also includes amorphous silicon nitride and can include silicon nitride having trace amounts of impurities.

Backside deposition may be performed by inserting the semiconductor wafer into a process chamber having both a top showerhead and a bottom showerhead (the bottom showerhead may be referred to as a showerhead pedestal, or a “shoped”), with wafer holders to hold the wafer between the two showerheads. Processing may be performed by positioning the wafer close to the top showerhead and delivering process gases to the backside of the wafer via the bottom showerhead. In some embodiments, the wafer may be placed upside down to use the top showerhead to deliver gases to the backside of the wafer, but in many embodiments, the wafer is placed upright with the patterned regions facing up and process gases are delivered to the backside of the wafer from the bottom showerhead. In various embodiments, the backside of the wafer is substantially flat and is not patterned.

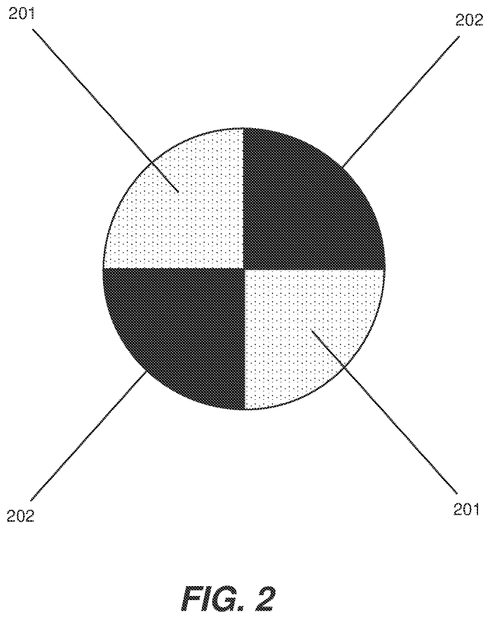

FIG. 2 shows a top view schematic illustration of an example bowed semiconductor substrate divided into regions of tensile stress and regions of compressive stress according to some implementations. In a bowed semiconductor substrate 200, tensile stress regions 201 and 203 are opposite regions, and compressive stress regions 202 and 204 are opposite regions. Tensile stress region 201 is adjacent to compressive stress regions 202 and 204. Compressive stress region 202 is adjacent to tensile stress regions 201 and 203. Tensile stress region 203 is adjacent to compressive stress regions 202 and 204. Compressive stress region 204 is adjacent to tensile stress regions 201 and 203. In some embodiments, the regions 201, 202, 203, 204 may be quadrants.

Compressive films such as compressive silicon oxide films may be deposited in compressive stress regions 202 and 204. Tensile films such as tensile silicon nitride films may be deposited in tensile stress regions 201 and 203. The combination of compressive film(s) and tensile film(s) provides localized stress modulation. In some instances, precursor zoning techniques may deliver precursor material to particular regions of the bowed semiconductor substrate 200. One technique may involve precursor zoning masks provided on the backside of the bowed semiconductor substrate 200. For instance, a carrier ring supporting the bowed semiconductor substrate 200 may be designed with a carrier ring mask for masking certain regions of the bowed semiconductor substrate 200 during deposition. Another technique may involve a multi-plenum showerhead to control delivery of gas to different locations. For example, precursor material for depositing compressive films may be delivered through first zones of the showerhead pedestal and precursor material for depositing tensile films may be delivered through second zones of the showerhead pedestal.

Bow compensation may be achieved with a mixture of oxide films and nitride films deposited at different regions of a bowed semiconductor substrate. The mixture of oxide films and nitride films may be deposited in asymmetrically bowed semiconductor substrates, including semiconductor substrates that have saddle-shaped bowing. Oxide films such as silicon oxide films are thermally stable and nitride films such as silicon nitride films are also thermally stable. An oxide film with compressive stress can be combined with a nitride film with tensile stress to provide thermally stable bow compensation layers. As used herein, “thermally stable” films can refer to films that do not change by more than 50% in stress value when exposed to elevated temperatures greater than deposition temperatures in which the film is deposited. In other words, “thermally stable” films do not undergo a stress shift greater than 50% at high temperatures. Elevated or high temperatures may include annealing temperatures equal to or greater than about 650° C., equal to or greater than about 700° C., equal to or greater than about 750° C., equal to or greater than about 800° C., or equal to or greater than about 850° C. By way of an example, a tensile film that changes from a stress value of 1 GPa to 2 GPa when annealed at 850° C. undergoes a stress shift of about 100%.

However, while applying a mixture of oxide films and nitride films may achieve a desired stress modulation, using a mixture of oxide films and nitride films may have one or more drawbacks. When a mixture of oxide films and nitride films are deposited on a backside of a semiconductor substrate, this can lead to a more complex and expensive removal process when the films have to be stripped off. This can be due in part to differences in etch rate between oxide films and nitride films. In addition, depositing a mixture of oxide films and nitride films requires different deposition chemistries, which can necessitate a more costly tool setup.

Furthermore, silicon oxide films, including silicon oxide films deposited by PECVD, are usually limited to low stress values. Specifically, silicon oxide films deposited by PECVD generally have compressive stress values of less than 400 MPa, and may be even less than 350 MPa or even less than 300 MPa after annealing. The low stress values may be insufficient for adequate stress modulation. As a result, compressive oxide films are generally unable to achieve high bow values unless deposited as thicker layers. However, thicker layers may be undesirable because thicker layers may add higher costs when films need to be removed, may result in more amplified film non-uniformity issues, may result in problems in overlay, and may increase difficulties in chucking.

Nitride films deposited by PECVD may have compressive or tensile stress values. Compressive nitride films deposited by PECVD may have compressive stress values as high as 2000 MPa. However, compressive nitride films deposited by PECVD are often thermally unstable. Thermally unstable compressive nitride films can result in bow loss higher than 40% at high temperatures. When films undergo bow loss of more than 40%, such a film may no longer be capable of being integrated because the film may have to be removed and deposited again. This adds to the cost of integration. Furthermore, higher bow loss in the film usually results in reduced film quality (e.g., density), which means that the film is less resilient to downstream processes.

The present disclosure relates to methods of depositing thermally stable and highly compressive nitride films or, more particularly, methods of depositing thermally stable and highly compressive silicon nitride films. In some applications, the thermally stable nitride film may be deposited as a bow compensation layer to mitigate bowing in a semiconductor substrate. In some other applications, the thermally stable nitride film may be deposited as diffusion barrier layer, cap layer, etch stop layer, spacer layer, or other layer requiring thermal stability in semiconductor processing. The thermally stable nitride film may be deposited by PECVD at low deposition temperatures. In some embodiments, the thermally stable nitride film is deposited with a compressive film stress equal to or greater than about 400 MPa and with a stress shift equal to or less than 50% of the compressive film stress when exposed to a temperature greater than its deposition temperature.

By depositing a thermally stable nitride film at low deposition temperatures, the deposition process of the present disclosure avoids high temperatures that may adversely affect temperature-sensitive underlayers. The thermally stable nitride film may achieve a highly compressive stress value that is preserved or substantially maintained even when exposed to elevated temperatures during subsequent processing (e.g., annealing). The highly compressive stress values achieved by thermally stable nitride films of the present disclosure are significantly higher than those of thermally stable oxide films. Though current solutions that are thermally stable may achieve compressive film stress of up to 400 MPa, the thermally stable compressive nitride film of the present disclosure can push compressive film stress even higher (e.g., up to about 2000 MPa). Accordingly, in some embodiments, a mixture of tensile nitride films and compressive nitride films may be deposited at different regions of a bowed semiconductor substrate for stress modulation. This provides one film type on the backside of the bowed semiconductor substrate, and this avoids the drawbacks of depositing a mixture of tensile nitride films and compressive oxide films for stress modulation as discussed above.

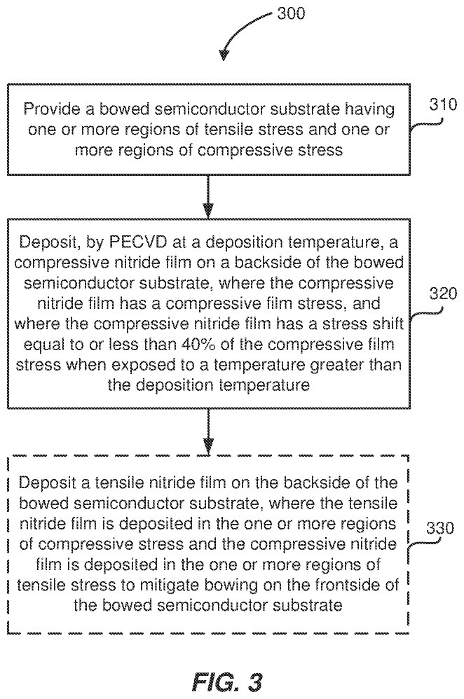

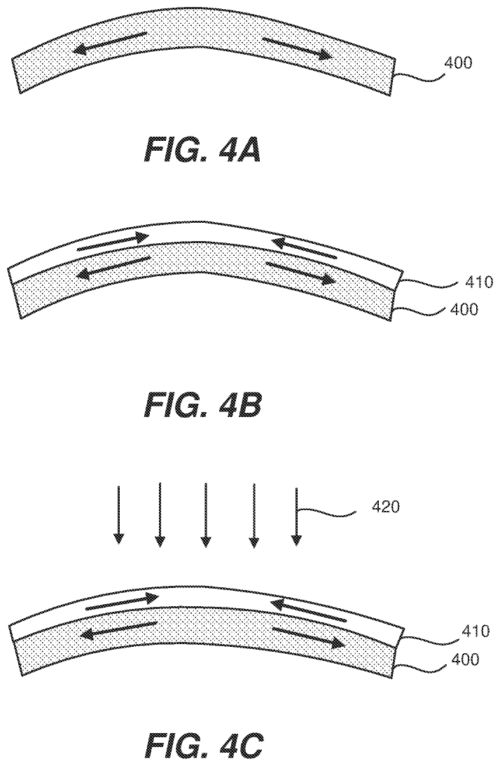

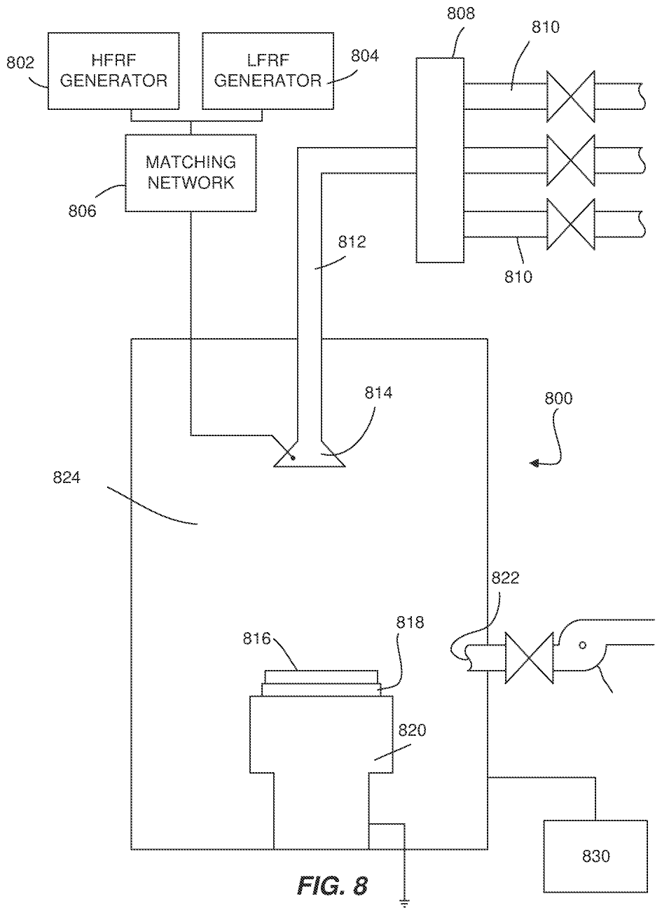

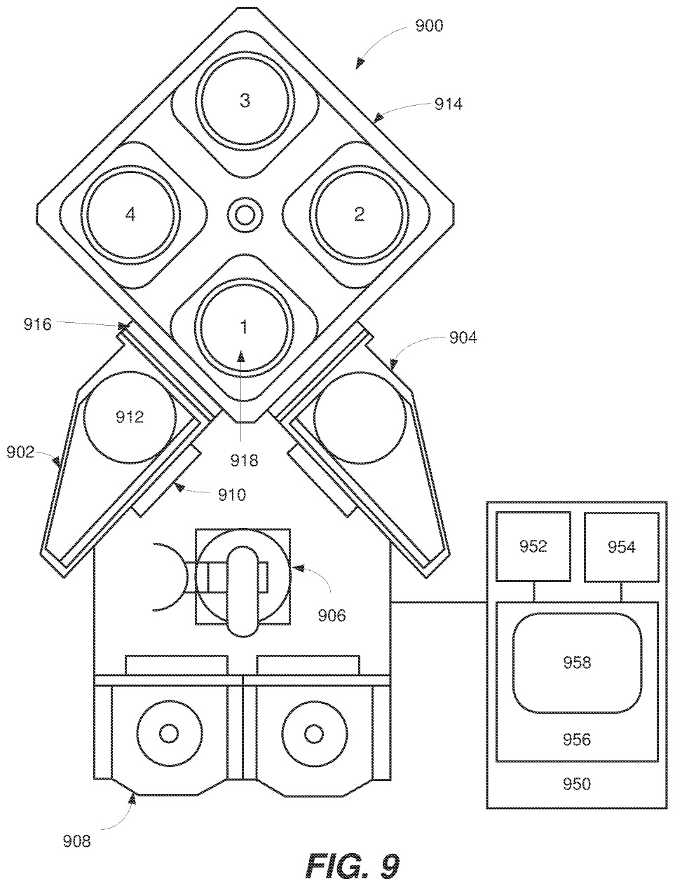

FIG. 3 illustrates a flow diagram of an example method of depositing a compressive nitride film on a bowed semiconductor substrate according to some implementations. The operations of a process 300 may be performed in different orders and/or with different, fewer, or additional operations. The operations of the process 300 may be described according to the various stages of forming a bow compensation layer in FIGS. 4A-4C. The operations of the process 300 may be performed using an apparatus for film deposition in FIGS. 8-9. In some implementations, the operations of the process 300 may be implemented, at least in part, according to software stored in one or more non-transitory computer readable media.

At block 310 of the process 300, a bowed semiconductor substrate having one or more regions of tensile stress and one or more regions of compressive stress is provided. A bowed semiconductor substrate refers to any semiconductor substrate that has a surface that deviates from a flat reference plane. In particular, a bowed semiconductor substrate may have warpage that exceeds ±300 μm. The bowed semiconductor substrate may be provided in a process chamber for performing backside deposition. In some embodiments, the bowed semiconductor substrate may be asymmetrically bowed. In some implementations, the bowed semiconductor substrate is saddle-shaped.

The substrate may be a silicon wafer, such as a 200-mm wafer, 300-mm wafer, or a 450-mm wafer, including wafers having one or more layers of material, such as dielectric, conducting, or semiconducting materials deposited on a frontside of the substrate. Some of the one or more layers may be patterned. Non-limiting examples of layers include dielectric layers and conducting layers such as silicon oxides, silicon nitrides, silicon carbides, metal oxides, metal nitrides, metal carbides, and metal layers. In various implementations, the substrate is patterned.

In some implementations, the bowed semiconductor substrate includes a patterned 3D-NAND structure and one or more etched trenches in the substrate.

The bowed semiconductor substrate may have a warpage of at least about ±1000 μm. In some implementations, the bowed semiconductor substrate has a warpage greater than about ±300 μm. In some implementations, the bowed semiconductor substrate has a warpage greater than about ±300 μm and less than about ±1000 μm. The warpage may occur at one or more localized regions of the bowed semiconductor substrate. The warpage may have different values between an x-axis warpage and y-axis warpage. The warpage may be a result of anisotropic stress distribution in the semiconductor substrate.

As used herein, tensile regions create localized tensile stress that induces warpage having positive values. Tensile regions cause localized concave bending of the semiconductor substrate. As used herein, compressive regions create localized compressive stress that induces warpage having negative values. Compressive regions cause localized convex bending of the semiconductor substrate. The one or more tensile regions and the one or more compressive regions are attributable to the one or more layers of materials on the substrate.

In some implementations, the bowed semiconductor substrate is provided in a process chamber for performing a deposition operation. The process chamber for performing the deposition operation may be configured for backside or frontside deposition. In some implementations, the process chamber is configured for backside deposition. In such instances, the semiconductor substrate may be provided in the process chamber having a wafer holder and a bottom showerhead for delivering gases to the backside of the semiconductor substrate. Delivery of first gases may be controlled to the one or more tensile regions and delivery of second gases may be controlled to the one or more compressive regions on the backside of the semiconductor substrate. In some implementations, the controlled delivery of gases to different regions of the semiconductor substrate may be accomplished using a carrier ring mask, zoning mask, multi-plenum showerhead, or other suitable technique. Some example techniques for controlled delivery of gases to different regions of the bowed semiconductor substrate are described in U.S. patent application Ser. No. 16/147,061 to Liu et al., entitled “ASYMMETRIC WAFER BOW COMPENSATION BY CHEMICAL VAPOR DEPOSITION,” filed Sep. 28, 2018, which is incorporated herein by reference in its entirety and for all purposes.

In some implementations, the bowed semiconductor substrate may be provided in the process chamber for performing deposition and aligned with the bottom showerhead. The process chamber, for example, may include wafer aligning technology to align regions (e.g., tensile or compressive stress regions) of the bowed semiconductor substrate with corresponding regions of the bottom showerhead.

FIG. 4A shows a cross-sectional schematic illustration of a bowed semiconductor substrate. A frontside of the semiconductor substrate 400 may be patterned with structures (e.g., nanostructures) leading to isotropic or anisotropic stress distribution in the semiconductor substrate 400. The stress distribution may include a localized tensile region in the semiconductor substrate 400, causing concave bending in the localized region of the semiconductor substrate 400. The semiconductor substrate 400 may be symmetrically or asymmetrically bowed. For example, the semiconductor substrate 400 may be saddle-shaped. The semiconductor substrate 400 may have a warpage equal to or greater than about +300 μm or equal to or less than about −300 μm in one or both of the x-axis and y-axis directions. The semiconductor substrate 400 may be provided in a process chamber for deposition such as a process chamber for backside deposition.

Returning to FIG. 3, at block 320 of the process 300, a compressive nitride film is deposited by PECVD on a backside of the bowed semiconductor substrate at a deposition temperature. The compressive nitride film has a compressive film stress. The compressive nitride film has a stress shift equal to or less than about 40% when exposed to a temperature greater than the deposition temperature. In some embodiments, the compressive nitride film has a stress shift equal to or less than about 35%, equal to or less than about 30%, or equal to or less than about 25% when exposed to a temperature greater than the deposition temperature. In some cases, the stress shift that is equal to or less than about 40% may occur for temperatures greater than deposition temperatures up to 1000° C. In some embodiments, the compressive film stress of the compressive nitride film is equal to or greater than about 400 MPa. For instance, the compressive film stress of the compressive nitride film is between about 500 MPa and about 3000 MPa, between about 800 MPa and about 2500 MPa, or between about 1000 MPa and about 2000 MPa.

Deposition of the compressive nitride film occurs by PECVD. Deposition by PECVD may proceed by flowing a reactant into a process chamber, and optionally with a co-reactant, while exposing the bowed semiconductor substrate to plasma. The plasma may drive a gas phase reaction that results in deposition of film. The PECVD reactions may generally involve delivering reactant(s) to the semiconductor substrate continuously while the semiconductor substrate is exposed to plasma. In some embodiments, depositing the compressive nitride film includes exposing the backside of the bowed semiconductor substrate to a silicon-containing precursor and a nitrogen-containing reactant, and exposing the backside of the bowed semiconductor substrate to plasma to drive a reaction between the silicon-containing precursor and the nitrogen-containing reactant to deposit the compressive nitride film. By depositing on the backside of the bowed semiconductor substrate, the compressive nitride film avoids being deposited on circuits, transistors, and other device components on the frontside of the bowed semiconductor substrate.

In some implementations, the silicon-containing precursor being flowed into the process chamber may include but are not limited to silanes, halosilanes, and aminosilanes. A silane contains silicon and hydrogen, and may optionally include carbon to form organo-silanes. Example silanes are silane (SiH₄), disilane (Si₂H₆), trisilane (Si₃H₈), cyclotrisilane (Si₃H₆), tetrasilane (Si₄H₁₀), cyclotetrasilane (Si₄H₈), pentasilane (Si₅H₁₂), cyclopentasilane (Si₅H₁₀), hexasilane (Si₆H₁₄), cyclohexasilane (Si₆H₁₂), heptasilane (Si₇H₁₆), cycloheptasilane (Si₇H₁₄), octasilane (Si₈H₁₈), and the like. Example organosilanes include but are not limited to methylsilane, ethylsilane, isopropylsilane, t-butylsilane, dimethylsilane, diethylsilane, di-t-butylsilane, allylsilane, sec-butylsilane, t-hexylsilane, isoamylsilane, t-butyldisilane, di-t-butyldisilane, and the like. A halosilane contains silicon and at least one halogen group, and may or may not contain hydrogens and/or carbon groups. Examples of halosilanes are iodosilanes, bromosilanes, chlorosilanes, and fluorosilanes. Specific examples of halosilanes with hydrogen groups include but are not limited to monochlorosilane (MCS, SiH₃Cl), dichlorosilane (DCS, SiH₂Cl₂), trichlorosilane (TCS, SiHCl₃), Si₂H₄Cl₂, Si₃H₅Cl₃, and the like. Specific examples of halosilanes without hydrogen groups include but are not limited to silicon tetrachloride (STC, SiCl₄), hexachlorodisilane (HCDS, Si₂Cl₆), octachlorotrisilane (OCTS, Si₃Cl₈), or a combination thereof. Specific examples of halosilanes with carbon groups include but are not limited to chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, t-hexyldimethylchlorosilane, and the like. An aminosilane includes at least one nitrogen atom bonded to a silicon atom, but may also contain hydrogens, oxygens, halogens, and/or carbons. Examples of aminosilanes are mono-aminosilane (H₃Si(NH₂)), di-aminosilane (H₂Si(NH₂)₂), tri-aminosilane (HSi(NH₂)₃), and tetra-aminosilane (Si(NH₂)₄), as well as substituted mono-, di-, tri-, and tetra-aminosilanes, for example, t-butylaminosilane, methylaminosilane, tert-butylsilanamine, bis (tertiarybutylamino) silane (BTBAS, SiH₂(NHC(CH₃)₃)₂), tert-butyl silylcarbamate, SiH(CH₃)—(N(CH₃)₂)₂, SiHCl—(N(CH₃)₂)₂, (Si(CH₃)₂NH)₃, and the like. A further example of an aminosilane is trisilylamine (N(SiH₃)₃). Other potential silicon-containing precursors include tetraethylorthosilicate (TEOS), and cyclic and non-cyclic TEOS variants such as tetramethoxysilane (TMOS), fluorotriethoxysilane (FTES), trimethylsilane (TMS), octamethyltetracyclosiloxane (OMCTS), tetramethylcyclotetrasiloxane (TMCTSO), dimethyldimethoxysilane (DMDS), hexamethyldisilazane (HMDS), hexamethyldisiloxane (HMDSO), hexamethylcyclotrisiloxane (HMCTSO), dimethyldiethoxysilane (DMDEOS), methyltrimethoxysilane (MTMOS), tetramethyldisiloxane (TMDSO), 20 divinyltetramethyldisiloxane (VSI2), methyltriethoxysilane (MTEOS), dimethyltetramethoxydisiloxane (DMTMODSO), ethyltriethoxysilane (ETEOS), ethyltrimethoxysilane (ETMOS), hexamethoxydisilane (HMODS), bis (triehtoxysilyl) ethane (BTEOSE), bis (trimethoxysilyl) ethane (BTMOSE), dimethylethoxysilane (DMEOS), tetraethoxydimethyldisiloxane (TEODMDSO), 25 tetrakis (trimehtylsiloxy) silane (TTMSOS), tetramethyldiethoxydisiloxane (TMDEODSO), triethoxysilane (TIEOS), trimethoxysilane (TIMEOS), or tetrapropoxysilane (TPOS).

In some implementations, the nitrogen-containing reactant being flowed into the process chamber may include but are not limited to nitrogen (N₂), ammonia (NH₃), hydrazine (N₂H₄), and amines (e.g., amines bearing carbon). Examples of amines are methylamine, dimethylamine, ethylamine, isopropylamine, t-butylamine, di-t-butylamine, cyclopropylamine, sec-butylamine, cyclobutylamine, isoamylamine, 2-methylbutan-2-amine, trimethylamine, diisopropylamine, diethylisopropylamine, di-t-butylhydrazine, as well as aromatic amines, such as aniline and methylaniline; alicyclic amines, such as cyclohexylamine and dicyclohexylamine; and heterocyclic amines, such as pyrrole, pyrrolidine, pyrrolidone, pyridine, morpholine, pyrazine, piperidine, N-hydroxyethylpiperidine, oxazole, and thiazole. Amines may be primary, secondary, tertiary, or quaternary (for example, tetraalkylammonium compounds). A nitrogen-containing reactant may contain heteroatoms other than nitrogen, for example, hydroxylamine, t-butyloxycarbonyl amine, and N-t-butyl hydroxylamine are nitrogen-containing reactants.

In some embodiments, the reactant(s) being flowed into the process chamber may be flowed with inert or carrier gases. The inert or carrier gas may include helium (He), argon (Ar), neon (Ne), xenon (Xe), krypton (Kr), hydrogen (H₂), nitrogen (N₂), and the like.

Films deposited by PECVD may often contain a considerable amount of hydrogen. The amount of hydrogen in the film can affect the degree of stress in the film. In fact, the amount of hydrogen in the film can affect the degree of stress changes that takes place after exposure to elevated temperatures. Thus, thermal stability may be correlated with the hydrogen content of the film. High hydrogen content may result in thermally unstable films, whereas low hydrogen content may result in thermally stable films.

A nitride film such as a silicon nitride film deposited by PECVD may contain Si—H bonds and N—H bonds, in addition to Si—N bonds. Without being limited by any theory, exposing the silicon nitride film to temperatures greater than a deposition temperature causes the Si—H bonds to start breaking so that hydrogen atoms are released from the silicon nitride film. As Si—H bonds are broken and hydrogen atoms are released from the film, an internal bonding structure within the silicon nitride film reorganizes. Silicon and nitrogen atoms rearrange and reorganize in the film. This reorganization and rearrangement can induce stress changes in the silicon nitride film, resulting in high stress shifts at temperatures greater than deposition temperatures. Specifically, reduced stress shift in a silicon nitride film can be obtained by reducing an amount of Si—H bonds in a deposited silicon nitride film. Thus, the amount of Si—H bonds in a silicon nitride film can be a first order metric to predict thermal stability of the silicon nitride film. Deposition conditions may be tuned to ensure minimal hydrogen content in a nitride film. In fact, deposition conditions may be tuned to ensure minimal Si—H bonds in a silicon nitride film. That way, the silicon nitride film has little to no Si—H bonds in the silicon nitride film. In some embodiments, a number of N—H bonds is greater than a number of Si—H bonds in the silicon nitride film of the present disclosure, and a number of Si—N bonds is substantially greater than a number of Si—H bonds in the silicon nitride film of the present disclosure.

In some implementations, reducing an amount of hydrogen in a nitride film can be achieved by reducing a flow of reactant(s) containing hydrogen during PECVD. By way of an example, reducing a flow rate of silane into the process chamber can reduce the presence of Si—H bonds in a silicon nitride film deposited by PECVD. Additionally or alternatively, reducing a flow rate of ammonia or other hydrogen-containing reactant can reduce the presence of Si—H bonds or hydrogen content in the silicon nitride film deposited by PECVD. However, lowered flow rates of precursors/reactants containing hydrogen may not sufficiently reduce hydrogen content to ensure a thermally stable nitride film.

In some implementations, the flow rate of reactant(s) may depend on the type of reaction through which the nitride film is deposited. Where CVD/PECVD is used to deposit on the backside of the bowed semiconductor substrate, the flow rate of the silicon-containing precursor may be between about 10 sccm and about 1000 sccm, between about 50 sccm and about 500 sccm, or between about 50 sccm and about 100 sccm. The flow rate of a nitrogen-containing reactant may be between about 0.5 SLM and about 50 SLM, between about 1 SLM and about 40 SLM, or between about 2 SLM and about 30 SLM. The flow rate of inert gas may be between about 0 SLM and about 100 SLM, or between about 1 SLM and about 10 SLM. In some implementations, the flow rate of the silicon-containing precursor such as silane may be equal to or less than about 10% by volume, equal to or less than about 8% by volume, or equal to or less than about 5% by volume of a total gas flow of the gas mixture used in PECVD. By way of an illustration, a flow rate of silane may be between about 50 sccm and about 100 sccm, a flow rate of nitrogen gas may be equal to or greater than about 20 SLM, a flow rate of ammonia may be between about 0.5 SLM and about 5 SLM, and a flow rate of argon may be between about 0 SLM and about 10 SLM. In some implementations, silane may be highly diluted, where a flow rate ratio between the silicon-containing precursor and the nitrogen-containing reactant is approximately 1:400.

Reduced hydrogen content in the nitride film in the present disclosure can occur by controlling a ratio of low-frequency RF power (LF RF power) to high-frequency RF power (HF RF power). In PECVD processing, one or more RF signals may be utilized to generate plasma for driving a reaction between reactant(s). The one or more RF signals may be generated from a low-frequency RF power supply and a high-frequency RF power supply, where plasma is ignited using a dual-RF plasma source that includes a low-frequency component and a high-frequency component. Low-frequency RF power refers to an RF power having a frequency between about 10 kHz and about 2 MHZ. Example frequencies for low-frequency components are 356 kHz and about 400 kHz. Example low-frequency powers may range between about 0-5000 W or between about 0-2500 W per station of a multi-station fabrication chamber. High-frequency RF power refers to an RF power having a frequency between about 2 MHz and about 27 MHz. Example frequencies for high-frequency components are 13.56 MHz and 27.0 MHz. Example high-frequency powers may range between about 0-5000 W or between about 0-2500 W per station of a multi-station fabrication chamber. In some implementations, the low-frequency power may be equal to or less than about 40% of a total RF power applied between the low-frequency component and the high-frequency component.

In depositing nitride films with compressive stress by PECVD, low-frequency and high-frequency RF powers are applied in generating plasma. Ordinarily, the low-frequency RF power is greater than the high-frequency RF power when depositing nitride films with compressive stress. In fact, as the low-frequency RF power increases, the tensile stress response of the film may decrease while the compressive stress response of the film may increase. The ratio of low-frequency RF power to high-frequency RF power may be about 5:1 or greater, 4:1 or greater, 3:1 or greater, or 2:1 or greater.

In the present disclosure, however, decreasing the low-frequency RF power relative to the high-frequency RF power increases thermal stability of a compressive nitride film deposited by PECVD. In some embodiments, the low-frequency RF power is less than the high-frequency RF power. For example, the low-frequency RF power is equal to or less than about 40% of a total RF power applied between the low-frequency RF power and the high-frequency RF power. The ratio of low-frequency RF power to high-frequency RF power may be about 1:5 or less, 1:4 or less, 1:3 or less, 1:2 or less, or 1:1 or less. In some embodiments, the low-frequency RF power may be equal to or less than about 40%, equal to or less than about 30%, or equal to or less than about 20% of a total RF power applied in the dual-RF plasma source. The compressive nitride film exhibits a reduced stress shift at temperatures greater than deposition temperatures when the low-frequency RF power is diminished relative to the high-frequency RF power. Though the low-frequency RF power is reduced, the nitride film may be highly compressive when other deposition parameters are controlled.

The temperature of the substrate may be controlled during deposition. In some embodiments, as the temperature of the substrate increases, the compressive stress response of the nitride film increases. That is, the substrate temperature may be tuned to modulate stress in a compressive nitride film. Higher temperatures may be used to obtain higher stress or greater thermal stability in a film being deposited. For example, the temperature of the substrate may be between about 50° C. and about 650° C., between about 100° C. and about 650° C., between about 200° C. and about 600° C., or between 400° C. and about 600° C.

The pressure in the process chamber may be controlled during deposition. In some embodiments, as the pressure in the process chamber increases, the compressive stress response of the nitride film decreases. Thus, the lower the pressure in the process chamber, the higher the compressive stress in the nitride film. For example, the pressure in the process chamber may be between about 0.01 Torr and about 20 Torr, between about 0.05 Torr and about 10 Torr, or between about 0.1 Torr and about 5 Torr.

Lower pressures, higher temperatures, lower flow rates of silicon-containing precursors (e.g., lower flow rate of silane, e.g., less than about 5% by volume of the total gas flow), and higher low-frequency RF powers generally result in more highly compressive nitride films. However, lower pressures, higher temperatures, and lower flow rates of silicon-containing precursors may provide highly compressive nitride films while having lower low-frequency RF powers (relative to high-frequency RF powers) may provide thermally stable, highly compressive nitride films. Controlling the foregoing deposition parameters may tune the compressive stress values and the stress shifts (i.e., thermal stability) of the compressive nitride film.

In some implementations, the compressive nitride film has a compressive stress that is tunable. The compressive stress value of the compressive nitride film may be tuned by controlling deposition parameters such as flow rates of silicon-containing precursors and/or nitrogen-containing reactants, flow rate of inert gas(es), process chamber pressure, substrate temperature, amount of low-frequency RF power, amount of high-frequency RF power, duration of plasma exposure, and spacing between electrodes, among other factors. In some implementations, the compressive film stress of the compressive nitride film is between about 500 MPa and about 3000 MPa, between about 800 MPa and about 2500 MPa, or between about 1000 MPa and about 2000 MPa. As discussed below, the thickness of the compressive nitride film may also be controlled to tune an amount of induced wafer bowing.

The degree of induced wafer bowing caused by a compressive nitride film may be dependent on a thickness of the compressive nitride film. The greater the thickness of the compressive nitride film, the greater the induced wafer bowing. Increasing the thickness of the compressive nitride film can mitigate larger amounts of warpage in the bowed semiconductor substrate. For a silicon nitride film of the present disclosure, however, the thickness of the PECVD-deposited silicon nitride film may be less than a thickness of a PECVD-deposited silicon oxide film for inducing the same amount of bowing for wafer bow compensation. Put another way, the thickness required to achieve a desired amount of induced wafer bowing is less for a

PECVD-deposited silicon nitride film of the present disclosure than a PECVD-deposited silicon oxide film. In some implementations, the PECVD-deposited silicon nitride film may induce at least two times more or at least three times more wafer bowing than the PECVD-deposited silicon oxide film having the same thickness. For instance, if a PECVD-deposited silicon oxide requires a thickness of 1 μm to induce a wafer bow of −500 μm, then a PECVD-deposited silicon nitride film of the present disclosure may require only a thickness of 300 nm to induce the same wafer bow of −500 μm. In some implementations, the compressive nitride film of the present disclosure has a thickness equal to or less than about 1000 nm, equal to or less than about 500 nm, equal to or less than about 300 nm, between about 10 nm and about 300 nm, or between about 20 nm and about 250 nm.

In some implementations, the compressive nitride film is thermally stable with a low stress shift at elevated temperatures. That way, when the compressive nitride film undergoes subsequent substrate processing such as annealing, the compressive stress of the compressive nitride film does not substantially change. When the stress value of the film does not substantially change (e.g., stress shifts not greater than 50%) at a temperature greater than the deposition temperature, the film may be considered thermally stable. In some embodiments, the compressive nitride film has a stress shift equal to or less than about 40%, equal to or less than about 35%, equal to or less than about 30%, or equal to or less than about 25% when exposed to a temperature greater than the deposition temperature. For example, the compressive nitride film has a stress shift equal to or less than about 40%, equal to or less than about 35%, equal to or less than about 30%, or equal to or less than about 25% when exposed to a temperature greater than the deposition temperature up to 1000° C.

In some embodiments, the compressive nitride film is a doped or undoped silicon nitride film. In one example, the compressive nitride film includes undoped silicon nitride (SiₓN_{y}). In another example, the compressive nitride film includes oxygen-doped silicon nitride (SiₓO_{y}N_{z}). In yet another example, the compressive nitride film includes carbon-doped silicon nitride (SiₓC_{y}N_{z}). In still yet another example, the compressive nitride film includes oxygen-and carbon-doped silicon nitride. Such compressive nitride films may be deposited by PECVD in a manner to achieve a thermally stable doped or undoped silicon nitride film.

The compressive nitride film may be deposited on the backside of the bowed semiconductor substrate in at least the one or more regions having tensile stress. The compressive nitride film mitigates bowing in the one or more tensile regions of the bowed semiconductor substrate. Where the bowed semiconductor substrate also has one or more compressive regions, a tensile nitride film may be deposited on the backside of the bowed semiconductor substrate.

FIG. 4B shows a cross-sectional schematic illustration of the bowed semiconductor substrate of FIG. 4A with a silicon nitride film deposited on a surface of the bowed semiconductor substrate. A silicon nitride film 410 may be deposited by PECVD on the bowed semiconductor substrate 400. The silicon nitride film 410 may be deposited under conditions so that the silicon nitride film 410 is highly compressive and thermally stable. During PECVD, a silicon-containing precursor and nitrogen-containing reactant is flowed towards the bowed semiconductor substrate 400 in a process chamber. For example, the silicon-containing precursor may include silane or TEOS, and the nitrogen-containing reactant may include nitrogen or ammonia. The bowed semiconductor substrate 400 is exposed to plasma to drive a reaction between the silicon-containing precursor and the nitrogen-containing reactant to deposit the silicon nitride film 410. The plasma may be generated from a dual-frequency plasma source having a high-frequency component and a low-frequency component. In some embodiments, the low-frequency RF power of the dual-frequency plasma source is less than the high-frequency RF power of the dual-frequency plasma source. In some embodiments, the low-frequency RF power of the dual-frequency plasma source is at least two times or at least three times less than the high-frequency RF power of the dual-frequency plasma source. Other deposition parameters such as flow rates, composition, plasma power, substrate temperature, process chamber pressure, duration of plasma exposure, RF duty cycle, RF pulsing, and electrode spacing may be optimized to deposit a highly compressive and thermally stable silicon nitride film 410. The silicon nitride film 410 may be deposited on the backside of the bowed semiconductor substrate 400 to mitigate bowing where there are tensile regions in the bowed semiconductor substrate 400.

Returning to FIG. 3, at block 330 of the process 300, a tensile nitride film is optionally deposited on the backside of the bowed semiconductor substrate, where the tensile nitride film is deposited in the one or more regions of compressive stress and the compressive nitride film is deposited in the one or more regions of tensile stress to mitigate bowing on the frontside of the bowed semiconductor substrate. The tensile nitride film may be deposited by PECVD. The mixture of compressive nitride film and tensile nitride film provides bow compensation for modulating stress in the bowed semiconductor substrate. In some implementations, the compressive nitride film and the tensile nitride film may be identical in composition. That way, the same type of film is deposited on the backside of the bowed semiconductor substrate for mitigating stress in both tensile and compressive regions of the bowed semiconductor substrate.

In some implementations, the tensile nitride film is a doped or undoped silicon nitride film. A tensile silicon nitride film may be deposited using any suitable silicon-containing precursor such as silane or TEOS and any suitable nitrogen-containing reactant such as nitrogen or ammonia. A ratio of flow rate of silicon-containing gas to nitrogen-containing gas may be between about 1:30 and about 1:40, such as about 1:36. An example range of high-frequency RF power may be between about 840 W and about 2400 W, or about 1200 W per station of a multi-station fabrication chamber.

In some implementations, the process 300 further includes annealing the bowed semiconductor substrate. Annealing the bowed semiconductor substrate may expose the substrate to temperatures equal to or greater than about 650° C., equal to or greater than about 700° C., equal to or greater than about 750° C., equal to or greater than about 800° C., or equal to or greater than about 850° C. The compressive stress of the compressive nitride film does not substantially change after annealing. Specifically, the compressive stress of the compressive nitride film does not change by more than 40%, by more than 35%, by more than 30%, or by more than 25% after annealing. In some implementations, the tensile stress of the tensile nitride film also does not substantially change after annealing. Both the compressive nitride film and the tensile nitride film may be thermally stable during annealing or other high-temperature operations.

FIG. 4C shows a cross-sectional schematic illustration of the bowed semiconductor substrate of FIG. 4B with the PECVD-deposited silicon nitride film after annealing. As shown in FIG. 4C, the silicon nitride film 410 reduces bowing induced by localized tensile regions in the bowed semiconductor substrate 400. The bowed semiconductor substrate 400 may be exposed to a high-temperature operation 420 such as annealing. Even when the bowed semiconductor substrate 400 is exposed to an elevated temperature greater than a deposition temperature of the silicon nitride film 410, the compressive stress of the silicon nitride film 410 does not substantially change.

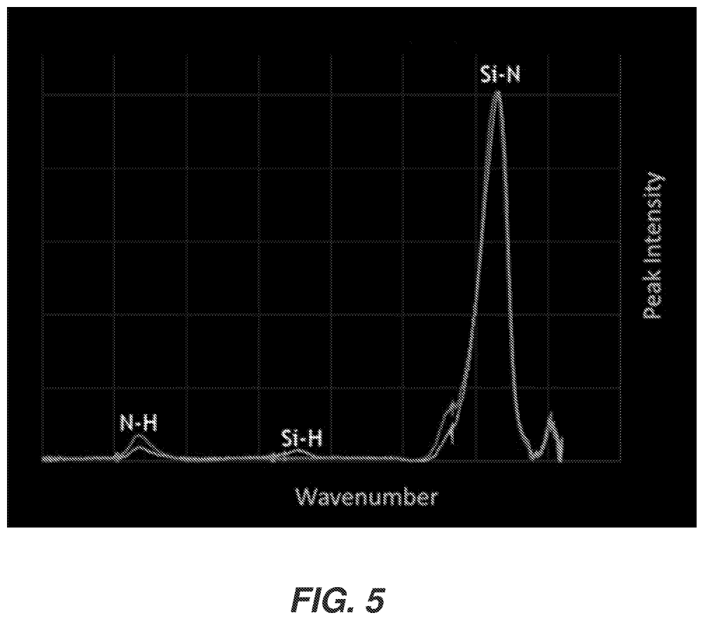

FIG. 5 illustrates a graph showing an IR spectrum for a conventional silicon nitride film deposited by plasma enhanced chemical vapor deposition (PECVD) and an IR spectrum for a high-stress, thermally-stable silicon nitride film deposited by PECVD according to some implementations. The silicon nitride film deposited under conventional PECVD conditions may be deposited under conditions using a dual-frequency plasma source such that the low-frequency RF power is greater than the high-frequency RF power. The silicon nitride film deposited under PECVD conditions of the present disclosure may be deposited using a dual-frequency plasma source such that the low-frequency RF power is less than the high-frequency RF power. The silicon nitride films in both cases are highly compressive and have at least Si—N bonds and N—H bonds. However, as indicated by the IR spectrum in FIG. 5, the silicon nitride film deposited under conventional PECVD conditions have Si—H bonds as revealed by a small peak indicative of Si—H bonding, while the silicon nitride film deposited under PECVD conditions of the present disclosure have little to no Si—H bonds. The PECVD-deposited silicon nitride film of the present disclosure may have more N—H bonds than Si—H bonds, and the PECVD-deposited silicon nitride film of the present disclosure may have more Si—N bonds than either N—H bonds or Si—H bonds.

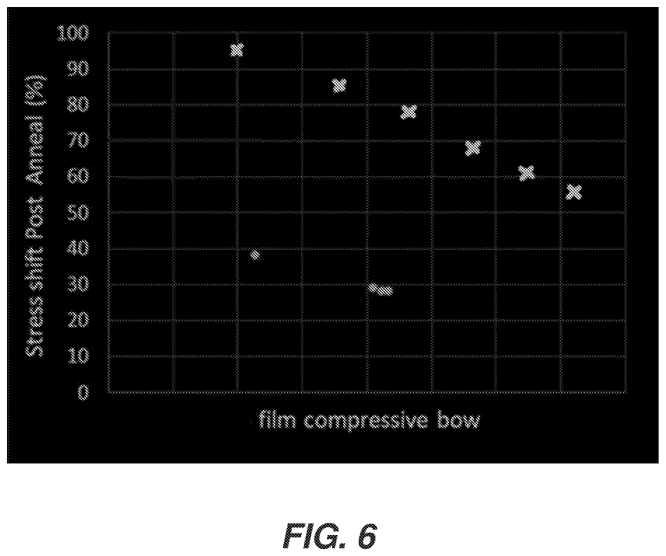

FIG. 6 shows a graph illustrating stress shift for a conventional silicon nitride film deposited by PECVD and a stress shift for a high-stress, thermally-stable silicon nitride film deposited by PECVD according to some implementations. The silicon nitride film deposited under conventional PECVD conditions (indicated by “x's”) may be deposited under conditions using a dual-frequency plasma source such that the low-frequency RF power is greater than the high-frequency RF power. The silicon nitride film deposited under conventional PECVD conditions exhibits a stress shift greater than 50% after annealing, whether the silicon nitride film is deposited with a small compressive bow or a large compressive bow. The silicon nitride film deposited under PECVD conditions of the present disclosure (indicated by “⋅”) may be deposited using a dual-frequency plasma source such that the low-frequency RF power is less than the high-frequency RF power. The silicon nitride film deposited under PECVD conditions of the present disclosure exhibits a stress shift less than 40% after annealing, whether the silicon nitride film is deposited with a small compressive bow or a large compressive bow.

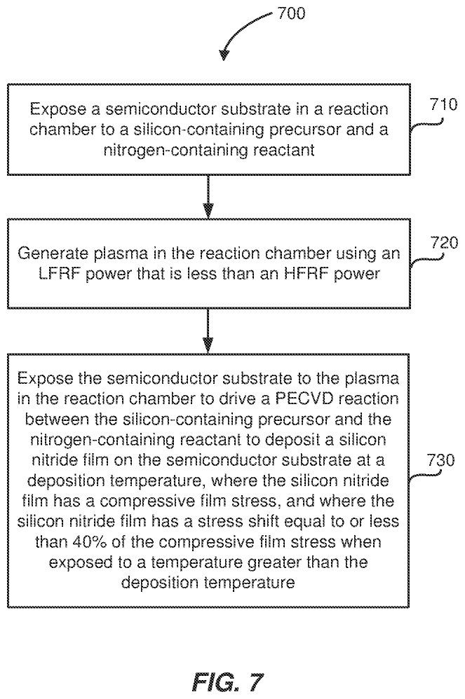

FIG. 7 illustrates a flow diagram of an example method of depositing a silicon nitride film on a semiconductor substrate according to some implementations. The operations of a process 700 may be performed in different orders and/or with different, fewer, or additional operations. The operations of the process 700 may be performed using an apparatus for film deposition in FIGS. 8-9. In some implementations, the operations of the process 300 may be implemented, at least in part, according to software stored in one or more non-transitory computer readable media.

At block 710 of the process 700, a semiconductor substrate is exposed to a silicon-containing precursor and a nitrogen-containing reactant in a reaction chamber. The semiconductor substrate may be a silicon substrate, such as a 200-mm, 300-mm, or 450-mm substrate, including substrates having one or more layers of material, such as dielectric, conducting, or semiconducting material. In some implementations, the semiconductor substrate on which silicon nitride films are deposited may include one or more layers that are sensitive to high temperatures such as temperatures equal to or greater than 650° C. In some implementations, the semiconductor substrate is provided in the reaction chamber prior to exposure to the silicon-containing precursor and the nitrogen-containing reactant. The reaction chamber may be configured for plasma processing, where the reaction chamber may include a dual-frequency plasma source.

In some embodiments, the silicon-containing precursor may include any silane, halosilane, or aminosilane as discussed above. For example, the silicon-containing precursor includes silane. In some embodiments, the nitrogen-containing reactant may include nitrogen, ammonia, hydrazine, or amines as discussed above. For example, the nitrogen-containing reactant includes nitrogen. Or, the nitrogen-containing reactant includes a combination of nitrogen and ammonia. The silicon-containing precursor and the nitrogen-containing reactant may be flowed continuously towards the semiconductor substrate.

At block 720 of the process 700, plasma in the reaction chamber is generated using LFRF power that is less than HFRF power. In some embodiments, the LFRF power is equal to or less than 40% of a total RF power applied by the LFRF power and the HFRF power. The reaction chamber may be configured to generate the plasma using a dual-RF plasma source that includes a low-frequency component for generating LFRF power and a high-frequency component for generating HFRF power. The low-frequency component and the high-frequency component may apply one or more RF signals for generating the plasma in the reaction chamber. By controlling a ratio of LFRF power to HFRF power, a number of Si—H bonds in the silicon nitride film being deposited is tuned. By lowering the number of Si—H bonds in the silicon nitride film, the thermal stability of the silicon nitride film is increased. In some implementations, the ratio of LFRF power to HFRF power may be about 1:5 or less, 1:4 or less, 1:3 or less, 1:2 or less, or 1:1 or less.

At block 730 of the process 700, the semiconductor substrate is exposed to the plasma in the reaction chamber to drive a PECVD reaction between the silicon-containing precursor and the nitrogen-containing reactant to deposit a silicon nitride film on the semiconductor substrate at a deposition temperature. The silicon nitride film has a compressive film stress, where the silicon nitride film has a stress shift equal to or less than 40% of the compressive stress when exposed to a temperature greater than the deposition temperature. The temperature may be greater than the deposition temperature up to 1000° C.

The degree of compressive stress and the stress shift of the silicon nitride film may be tuned by controlling one or more deposition parameters in the PECVD reaction. Non-limiting examples of deposition parameters include gas flow rates, gas composition, plasma power (e.g., LFRF power, HFRF power), temperature, pressure, duration of plasma exposure, RF duty cycle, RF pulsing, and electrode spacing. In some implementations, the flow rate of the silicon-containing precursor is between about 10 sccm and about 1000 sccm, or between about 50 sccm and about 50 sccm, the flow rate of nitrogen-containing reactant is between about 0.1 SLM and about 50 SLM, or between about 1 SLM and about 40 SLM. In some implementations, the flow rate of inert gas may be between about 0 SLM and about 100 SLM, or between about 1 SLM and about 10 SLM. In some implementations, the flow rate of the silicon-containing precursor (e.g., silane) is equal to or less than about 10% by volume, equal to or less than about 8% by volume, or equal to or less than about 5% by volume of a total gas flow of a gas mixture in PECVD. In some implementations, a substrate temperature is between about 50° C. and about 650° C., between about 100° C. and about 650° C., between about 200° C. and about 600° C., or between 400° C. and about 600° C. In some implementations, a reaction chamber pressure is between about 0.1 Torr and about 20 Torr, between about 0.5 Torr and about 10 Torr, or between about 1 Torr and about 5 Torr. In some implementations, LFRF power may range from about 50 W to about 5000 W, or from 100 W to about 2500 W, and the HFRF power may range from about 50 W to about 5000 W, or from 100 W to about 2500 W. In some implementations, the duration of plasma exposure may be between about 5 seconds and about 60 minutes, between about 10 seconds and about 30 minutes, or between about 30 seconds and about 15 minutes. In some implementations, electrode spacing in the reaction chamber may be between about 2 mm and about 50 mm, or between about 5 mm and about 30 mm. To achieve a high-stress, thermally-stable silicon nitride film, the substrate temperature may be relatively high, the pressure may be relatively low, the flow rate of the silicon-containing precursor may be relatively low, and the LFRF power may be less than the HFRF power.

The silicon nitride film may have a high compressive film stress. The silicon nitride film may achieve compressive stress values greater than PECVD-deposited silicon oxide films. The compressive stress value of the silicon nitride film may be tunable by altering one or more deposition parameters. In some embodiments, the compressive film stress of the silicon nitride film is equal to or greater than about 400 MPa. For example, the compressive film stress of the silicon nitride film is between about 500 MPa and about 3000 MPa, between about 800 MPa and about 2500 MPa, or between about 1000 MPa and about 2000 MPa. The silicon nitride film may induce significant wafer bowing without having to deposit a thick film. In some implementations, the silicon nitride film has a thickness equal to or less than about 300 nm.

The silicon nitride film may be thermally stable. The compressive stress value does not substantially change after exposure to any temperature greater than the deposition temperature. The deposition temperature in PECVD may be equal to or less than about 650° C., equal to or less than about 600° C., or between about 200° C. and about 600° C. In some implementations, the stress shift of the silicon nitride film is equal to or less than about 35%, equal to or less than about 30%, or equal to or less than about 25% of the compressive film stress when exposed to a temperature greater than the deposition temperature. In some implementations, the anneal temperature may be equal to or greater than about 650° C., equal to or greater than about 700° C., equal to or greater than about 750° C., equal to or greater than about 800° C., or equal to or greater than about 850° C. For example, the silicon nitride film may be exposed to an annealing temperature between about 700° C. and about 1000° C., and the compressive film stress in the silicon nitride film does not change by more than 35%, by more than 30%, or by more than 25%.

In some implementations, the silicon nitride film may be deposited on a bowed semiconductor substrate having one or more tensile regions, where the silicon nitride film mitigates bowing in the one or more tensile regions of the bowed semiconductor substrate. Thus, the silicon nitride film deposited by PECVD may serve as a bow compensation layer. In some other implementations, the silicon nitride film deposited by PECVD may be a diffusion barrier layer, cap layer, etch stop layer, spacer layer, or other layer requiring thermal stability in semiconductor processing.

FIG. 8 shows a schematic diagram of an example plasma processing apparatus configured to perform PECVD according to some implementations. The plasma processing apparatus may be configured to deposit a compressive nitride film by PECVD according to the techniques described in the present disclosure.

As shown in FIG. 8, a plasma processing apparatus 800 includes a process chamber 824, which encloses other components of the plasma processing apparatus 800 and serves to contain a plasma. The process chamber 824 includes a showerhead 814 for delivering process gases into the process chamber 824. The process chamber 824 may be configured as a dual-frequency plasma source. A high-frequency radio-frequency (HFRF) generator 802 may be connected to an impedance matching network 806, which is connected to the showerhead 814. In some implementations, a low-frequency radio-frequency (LFRF) generator 804 may be connected to the impedance matching network 806 to connect to the showerhead 814. The power and frequency supplied by the impedance matching network 806 is sufficient to generate a plasma from process gas. In typical processes, a frequency generated by the HFRF generator 802 is between 2-60 MHz, such as 13.56 MHz or 27 MHz. A frequency generated by the LFRF generator 804 is between about 250-400 kHz, such as 350 kHz or 400 kHz. In some embodiments, the showerhead 814 and a pedestal 818 may electrically communicate with the HFRF generator 802, LFRF generator 804, and impedance matching network 806 for powering a plasma. In some embodiments, the plasma energy may be controlled by controlling one or more of a process chamber pressure, gas concentrations and partial pressures of gases or gas flow rates, plasma power and frequency to the HFRF generator 802, plasma power and frequency to the LFRF generator 804. In some embodiments, the HFRF generator 802 and the LFRF generator 804 may be controlled independently of one another. It will be appreciated that any suitable parameters may be modulated discretely or continuously to provide plasma energy for a reaction for depositing compressive nitride layer.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

The process chamber 824 further includes a wafer support or pedestal 818. The pedestal 818 may support a wafer 816. In some embodiments, the pedestal 818 can include a chuck, a fork, and/or lift pins to hold the wafer 816 during and between processing. In some implementations, the pedestal 818 is an electrostatic chuck. In some implementations, the pedestal 818 includes wafer holders to hold the wafer 816 by the edges so that a bottom showerhead (not shown) may deliver gases to a backside of the wafer 816.

In some embodiments, pedestal 818 may be temperature controlled via one or more heating elements (not shown). In some cases, the one or more heating units may be used to anneal the wafer 816. For example, in some embodiments, the one or more heating elements may maintain the wafer 816 at a temperature less than about 650° C. during deposition, or between about 100° C. and about 450° C. during deposition of a compressive nitride film of the present disclosure. The one or more heating elements may heat the wafer 816 to temperatures equal to or greater than about 650° C. in subsequent operations such as annealing.

Process gases may be introduced via inlet 812. One or more source gas lines 810 can be connected to a manifold 808. The process gases may be premixed or not. Appropriate valving and mass flow control mechanisms are employed to ensure that the correct gases are delivered during deposition and other processing operations. Process gases may exit the process chamber 824 via an outlet 822. A vacuum pump 826 can typically draw process gases out and maintain a suitably low pressure within the process chamber 824.

Though the showerhead 814 for delivery of process gases may appear oriented as a top showerhead, it will be understood that the showerhead 814 may be configured as a bottom showerhead or showerhead pedestal (“shoped”) for delivery of process gases to the backside of the wafer 816. Thus, a faceplate of the showerhead 814 may be configured to face the backside of the wafer 816 such as the backside of a bowed semiconductor substrate. For example, the showerhead 814 may distribute process gases for depositing a bow compensation layer such as a silicon nitride layer on the backside of the wafer 816, where the process gases may include a silicon-containing precursor, a nitrogen-containing reactant, and/or inert gas. The showerhead 814 may have any suitable shape, and may have any suitable number and arrangement of ports for distributing process gases to the wafer 816. A shield (not shown) may also be present in the process chamber 824.

As shown in FIG. 8, the plasma processing apparatus 800 is a capacitor-type system where the showerhead 814 is an electrode working in conjunction with a grounded block 820. In other words, the plasma processing apparatus 800 is a capacitively-coupled plasma (CCP) system and may be capable of supplying high-frequency RF power to the top of the process chamber 824, namely the showerhead 814. The bottom of the process chamber 824, namely the pedestal 818 and the block 820, may be grounded.

One of the apparatuses for performing deposition, such as the plasma processing apparatus 800, may be implemented in a multi-station processing tool. An example multi-station processing tool is described below.

FIG. 9 shows a schematic diagram of an example process tool for substrate processing

according to some implementations. The multi-station process tool 900 can include an inbound load lock 902 and an outbound load lock 904, either or both of which may comprise a plasma source and/or UV source. A robot 906, which may be at atmospheric pressure, is configured to move wafers from a cassette loaded through a pod 908 into inbound load lock 902 via an atmospheric port 910. A wafer (not shown) is placed by the robot 906 on a pedestal 912 in the inbound load lock 902, the atmospheric port 910 is closed, and the inbound load lock 902 is pumped down. Where the inbound load lock 902 includes a remote plasma source, the wafer may be exposed to a remote plasma treatment in the inbound load lock 902 prior to being introduced into a processing chamber 914. Further, the wafer also may be heated in the inbound load lock 902 as well, for example, to remove moisture and adsorbed gases. Next, a chamber transport port 916 to processing chamber 914 is opened, and another robot (not shown) places the wafer into the reactor on a pedestal of a first station shown in the reactor for processing. While the implementation depicted in FIG. 9 includes load locks, it will be appreciated that, in some implementations, direct entry of a wafer into a process station may be provided.

The depicted processing chamber 914 includes four process stations, numbered from 1 to 4 in the embodiment shown in FIG. 9. Each station has a heated pedestal (shown at 918 for station 1), and gas line inlets. It will be appreciated that in some embodiments, each process station may have different or multiple purposes. For example, in some embodiments, a process station may be switchable between a CVD and PECVD process mode. In another example, deposition operations such as PECVD operations may be performed in one station, while exposure to UV radiation for UV treatment may be performed in another station. While the depicted processing chamber 914 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 9 depicts an implementation of a wafer handling system 990 for transferring wafers within processing chamber 914. In some embodiments, wafer handling system 990 may transfer wafers between various process stations and/or between a process station and a load lock.

It will be appreciated that any suitable wafer handling system may be employed. Non-limiting examples include wafer carousels and wafer handling robots. FIG. 9 also depicts an implementation of a system controller 950 employed to control process conditions and hardware states of process tool 900. System controller 950 may include one or more memory devices 956, one or more mass storage devices 954, and one or more processors 952. Processor 952 may include a CPU or computer, analog, and/or digital input/output connections, stepper motor controller boards, etc.

In some embodiments, system controller 950 controls all of the activities of process tool 900. System controller 950 executes system control software 958 stored in mass storage device 954, loaded into memory device 956, and executed on processor 952. Alternatively, the control logic may be hard coded in the controller 950. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 958 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 900. System control software 958 may be configured in any suitable way. For example, various process tool component subroutines or control objects may be written to control operation of the process tool components used to carry out various process tool processes. System control software 958 may be coded in any suitable computer readable programming language.

In some embodiments, system control software 958 may include input/output control (IOC) sequencing instructions for controlling the various parameters described above. Other computer software and/or programs stored on mass storage device 954 and/or memory device 956 associated with system controller 950 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 918 and to control the spacing between the substrate and other parts of process tool 900. For example, the substrate positioning program may position the substrate at a particular spacing between electrodes in the processing chamber 914.

A process gas control program may include code for controlling gas composition (e.g., silicon-containing gases, nitrogen-containing gases, and dilution or inert gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. For example, the heating unit may include one or more heating elements such as light-emitting diodes (LEDs) in a pedestal for heating a backside of the substrate. Alternatively, the heater control program may control delivery of a heat transfer gas (such as helium) to the substrate.

A plasma control program may include code for setting RF power levels applied to the process electrodes in one or more process stations in accordance with the embodiments herein. The plasma control program may control distribution of RF power between an HFRF generator and an LFRF generator during deposition.

A pressure control program may include code for maintaining the pressure in the reaction chamber in accordance with the embodiments herein.

In some embodiments, there may be a user interface associated with system controller 950. The user interface may include a display screen, graphical software displays of the apparatus and/or process conditions, and user input devices such as pointing devices, keyboards, touch screens, microphones, etc.

In some embodiments, parameters adjusted by system controller 950 may relate to process conditions. Non-limiting examples include process gas composition and flow rates, temperature, pressure, plasma conditions such as RF frequencies, HFRF power, LFRF power, and duration of plasma exposure, spacing between electrodes, etc. These parameters may be provided to the user in the form of a recipe, which may be entered utilizing the user interface.

Signals for monitoring the process may be provided by analog and/or digital input connections of system controller 950 from various process tool sensors. The signals for controlling the process may be output on the analog and digital output connections of process tool 900. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 950 may provide program instructions for implementing the above-described deposition processes. The program instructions may control a variety of process parameters, such as DC power level, RF bias power level, pressure, temperature, etc. The instructions may control the parameters to operate deposition of film stacks of a bow compensation layer according to various embodiments described herein.

The system controller 950 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 950.

In some implementations, the system controller 950 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 950, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 950 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 950 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, nitrides (e.g., silicon nitride films), surfaces, circuits, and/or dies of a wafer.

The system controller 950, in some implementations, may be a part of or coupled to a computer that is integrated with, coupled to the system, otherwise networked to the system, or a combination thereof. For example, the system controller 950 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 950 receives instructions in the form of data, which specify parameters for each of the processing steps to be performed during one or more operations. It should be understood that the parameters may be specific to the type of process to be performed and the type of tool that the system controller 950 is configured to interface with or control. Thus as described above, the system controller 950 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

### Other Embodiments

In the foregoing description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments are described in conjunction with the specific embodiments, it will be understood that it is not intended to limit the disclosed embodiments.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method of depositing a compressive nitride film on a bowed semiconductor substrate, the method comprising:
providing a bowed semiconductor substrate having one or more regions of tensile stress and one or more regions of compressive stress; and
depositing, by plasma-enhanced chemical vapor deposition (PECVD) at a deposition temperature, a compressive nitride film on a backside of the bowed semiconductor substrate, wherein the compressive nitride film has a compressive film stress, and wherein the compressive nitride film has a stress shift equal to or less than 40% of the compressive film stress when exposed to a temperature greater than the deposition temperature.

2. The method of claim 1, wherein the compressive nitride film is undoped silicon nitride, oxygen-doped silicon nitride, or carbon-doped silicon nitride.

3. The method of claim 2, wherein the compressive nitride film is undoped silicon nitride.

4. The method of claim 1, wherein the compressive film stress of the compressive nitride film is equal to or greater than about 400 MPa.

5. The method of claim 4, wherein the compressive film stress of the compressive nitride film is between about 1000 MPa and about 2000 MPa.

6. The method of claim 1, wherein the stress shift of the compressive nitride film is equal to or less than 35% of the compressive film stress when exposed to a temperature equal to or greater than about 850° C.

7. The method of claim 1, further comprising:
depositing a tensile nitride film on the backside of the bowed semiconductor substrate, wherein the tensile nitride film is deposited in the one or more regions of compressive stress and the compressive nitride film is deposited in the one or more regions of tensile stress to mitigate bowing on a frontside of the bowed semiconductor substrate.

8. The method of claim 1, wherein depositing the compressive nitride film by PECVD comprises:
exposing the backside of the bowed semiconductor substrate to a silicon-containing precursor and a nitrogen-containing reactant; and
exposing the backside of the bowed semiconductor substrate to plasma to drive a reaction between the silicon-containing precursor and the nitrogen-containing reactant to deposit the compressive nitride film.

9. The method of claim 8, wherein the plasma is generated using a low-frequency radio-frequency (LFRF) power that is less than a high-frequency radio-frequency (HFRF) power.

10. The method of claim 9, wherein the LFRF power is equal to or less than about 40% of a total RF power applied between the LFRF power and the HFRF power.

11. The method of claim 8, wherein the silicon-containing precursor includes silane, wherein a flow rate of silane is equal to or less than about 5% by volume of a total gas flow of a gas mixture in PECVD.

12. The method of claim 1, wherein a number of N—H bonds is greater than a number of Si—H bonds in the compressive nitride film, and wherein a number of Si—N bonds is substantially greater than the number of Si—H bonds in the compressive nitride film.

13. A method of depositing a silicon nitride film on a semiconductor substrate, the method comprising:
exposing a semiconductor substrate in a reaction chamber to a silicon-containing precursor and a nitrogen-containing reactant;
generating plasma in the reaction chamber using an LFRF power that is less than an HFRF power; and
exposing the semiconductor substrate to the plasma in the reaction chamber to drive a PECVD reaction between the silicon-containing precursor and the nitrogen-containing reactant to deposit a silicon nitride film on the semiconductor substrate at a deposition temperature, wherein the silicon nitride film has a compressive film stress, and wherein the silicon nitride film has a stress shift equal to or less than 40% of the compressive film stress when exposed to a temperature greater than the deposition temperature.

14. The method of claim 13, wherein the compressive film stress of the silicon nitride film is equal to or greater than about 400 MPa.

15. The method of claim 14, wherein the compressive film stress of the silicon nitride film is between about 1000 MPa and about 2000 MPa.

16. The method of claim 13, wherein the stress shift is equal to or less than 35% of the compressive film stress when exposed to a temperature equal to or greater than about 850° C.

17. The method of claim 13, wherein the silicon nitride film has a thickness equal to or less than about 300 nm.

18. The method of claim 13, wherein the LFRF power is equal to or less than about 40% of a total RF power applied between the LFRF power and the HFRF power.

19. The method of claim 13, wherein a number of N—H bonds is greater than a number of Si—H bonds in the silicon nitride film, and wherein a number of Si—N bonds is substantially greater than the number of Si—H bonds in the silicon nitride film.

20. The method of claim 13, wherein the semiconductor substrate is a bowed semiconductor substrate having one or more tensile regions, wherein the silicon nitride film mitigates bowing in the one or more tensile regions of the bowed semiconductor substrate.
